(19) United States
(12) Patent Application Publication
(10) Pub. No.: US 2011/0042767 A1
(43) Pub. Date: Feb. 24, 2011

(54) FILTERS IN AN IMAGE SENSOR

(75) Inventors: Ewan Findlay, Dollar (GB); Robert Nicol, Lesmahagow (GB)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics (Research & Development) Limited, Marlow (GB)

(21) Appl. No.: 12/857,287

(22) Filed: Aug. 16, 2010

(30) Foreign Application Priority Data
Aug. 17, 2009 (GB) 0914350.4

(51) Int. Cl. H01L 31/0232; H01L 31/18

(52) U.S. Cl. 257/432; 438/65; 257/E31.127

(57) ABSTRACT

A method of forming an image sensor having a sensor, a cover, and a filter, that may include applying a filter layer to a cover layer by masking the cover layer with a predetermined pattern and applying the filter layer by a deposition process. The method may also include bonding the cover layer to a sensor layer including a plurality of sensors. The predetermined pattern may result in a filter layer which is aligned with each sensor. There may be gaps in the filter layer around each sensor.

### FIELD OF THE INVENTION

The present invention relates to filters in an image sensor, such as a chip scale package image sensor.

### BACKGROUND OF THE INVENTION

Chip scale package (CSP) image sensors are commonly used in mobile phone cameras and many other devices. These types of image sensors are relatively expensive to manufacture, however, in the long-term, increased yield may mitigate some of the expenses. A CSP for a typical image sensor may include a silicon chip, on which an image sensor is constructed, and a cover, such as glass, which may reduce ingress and contamination of the sensor surface during the construction process. A typical image sensor may also include bonding to bond the cover to the silicon and electrical connections between the active surface (i.e. the surface on which the sensor is built) and the rear thereby allowing signals to pass to external electronics where appropriate.

A CSP is typically manufactured using a wafer related process to bond a wafer of silicon to the cover. This combination of wafer and cover is then processed to provide connectivity before the wafer is cut into chip scale packages. This may often require a process for “thinning” the silicon wafer for back to front connectivity. This can be seen in FIG. 1 where the cover 100 is bonded to a silicon wafer 102 in a wafer level packaging-through silicon via (WLP-TSV) process. The silicon wafer generally undergoes backgrinding to allow the TSV process to be completed. The thinning of the silicon can be seen in the final combination 104 which is ready for the WLP-TSV processing. For the silicon and glass cover to be processed together it may be desirable to match the thermal expansion of the two parts to reduce the chance of the combined glass silicon wafer warping and eventually fracturing.

There are a number of advantages and disadvantages associated with current CSP image sensor packaging. Some of these disadvantages become accentuated when the CSP concept uses an IR to UV filter, which may be made by vacuum deposition of dielectric layers on a separate piece of glass.

Referring to FIG. 2, the deposition of a filter coating 200 onto the glass wafer 202 results in a compression stress that causes the glass wafer to bow or warp. Subsequent processing and the silicon/glass laminate 204 can give rise to thickness variations on the silicon, which are incompatible with TSV processing. The relatively high stress in the laminate during the grinding process may result in thinning of the wafer in the center thereof. This problem can be identified in a number of different scenarios where a filter is coated onto a glass element, such as an objective lens or micro lenses. Any curvature caused by depositing the filter layer may lead to spectral inconsistencies over the filter or element. This makes it harder to monitor the spectral response of the filters in certain situations.

Attempts to overcome the problems have relied on the use of glass that is expansion matched to the silicon and carried out as follows. The silicon and an uncoated glass wafer are typically prepared by bonding, revealing contacts, etc. The wafer is then cut to produce single CSPs that are cleaned and placed in a coating jig. The packages are then coated with a filter on the upper surface of the glass to complete the finished CSP. A disadvantage of this process is the production of particles during the cutting and handling of the CSP prior to application of the filter coating, which introduces contamination to the final CSP. This produces increased yield loss on a potentially expensive component during a low-cost part of the procedure.

Another attempt has been to coat the glass on both sides to try and keep the glass form flat. The process then proceeds to bond the silicon and coated glass wafer together and cut them into the individual modules. This process is typically highly accurate to ensure that any defect size is less than a pixel diagonal of the sensor on the lower surface. In addition there is potential for variations in the amount of coating which can continue to generate warping of the glass wafer and therefore uneven thinning of the silicon wafer.

### SUMMARY OF THE INVENTION

In view of the foregoing background, it is therefore an object of the present invention to overcome at least some of the problems associated with the prior art. A further object of the present invention is to make a CSP comprising a filter using deposition of dielectric layers as part of the CSP while in a wafer form.

The object is also accomplished by a device as set out in the accompanying claims. According to one embodiment, there is provided a method of forming an image sensor having a sensor, a cover, and a filter. The method may include applying a filter layer to a cover layer by masking the cover layer with a predetermined pattern, and applying the filter layer by a deposition process. The method may further include bonding the cover layer to a sensor layer including a plurality of sensors. The predetermined pattern may result in a filter layer which is aligned with each sensor and includes gaps in the filter layer around each sensor.

The present embodiment may provide a number of advantages, in particular, the problems of differential thermal expansion between a coating and the wafer scale package are significantly reduced thereby reducing yield loss. As stress considerations are less of an issue, the filter may be designed with other criteria, for example, achieving appropriate color accuracy for a camera in the final application. As stress is less of an issue, the glass layer may have a reduced thickness which may improve the space available for other camera elements. This may result in an improved camera tracked length. In some situations two different glass layers may be used: one for the cover and one to support the filter. The present embodiments may provide a means or an approach by which one layer of glass is used.

The present embodiments may also have a number of advantages in terms of handling the CSP and reducing contamination. As the filter layer may not be impacted by the cutting places, there is less debris and contamination. In addition, as the filter is applied by a deposition process, a clean room environment is typically maintained and less contamination is likely. The present embodiments may result in a higher yield without additional costs or processing.

### BRIEF DESCRIPTION OF THE DRAWINGS

Reference will now be made, by way of example, to the accompanying drawings, in which:

FIG. 1 is a flow diagram of a normal WLP-TSV process, in accordance with the prior art;

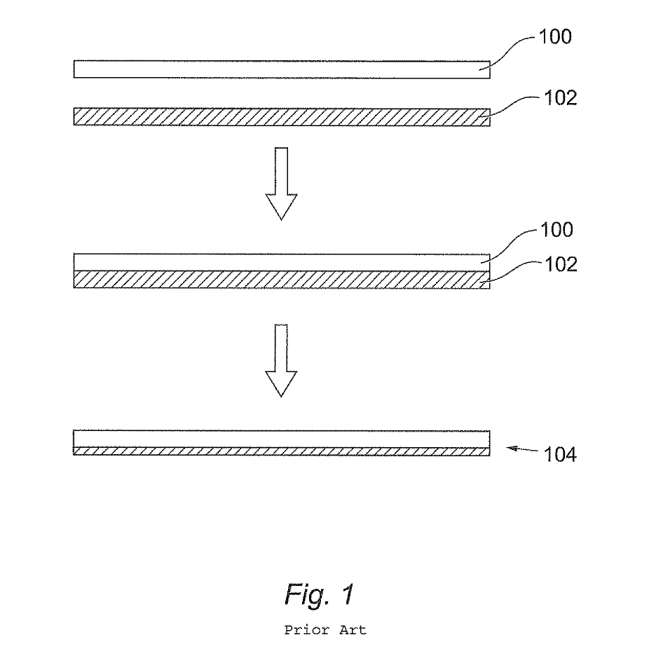

FIG. 2 is a flow diagram of the WLP-TSV process including an IR filter, in accordance with the prior art;

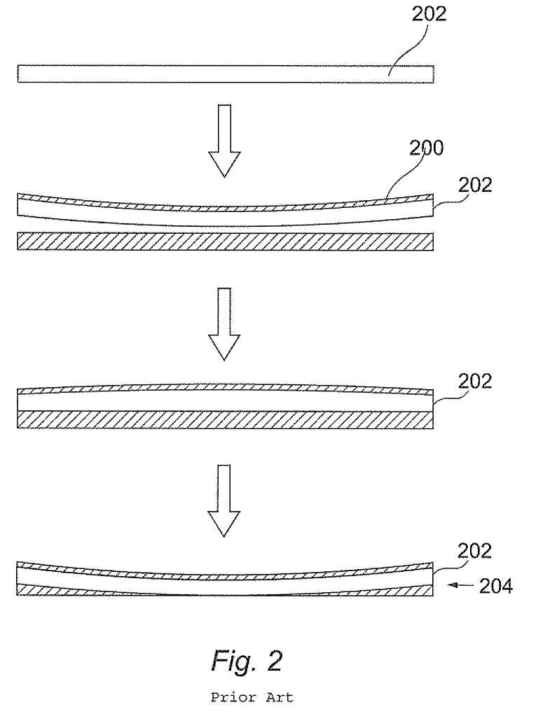

FIG. 3 is a flow chart of a WLP-TSV process including the addition of a filter, in accordance with an embodiment of the invention;

FIG. 4 is a flow chart of a WLP-TSV process in accordance with an embodiment of the invention; and

FIG. 5 is a top view of a glass wafer bonded to a silicon wafer, in accordance with an embodiment of the invention.

### DETAILED DESCRIPTION OF THE PREFERRED EMBODIMENTS

The present embodiments include a method and chip that reduce the effect of differential thermal expansion of the silicon and glass layers. This reduces production loss due to cutting the combined layer into individual chips, and enables the use of a viable coating process.

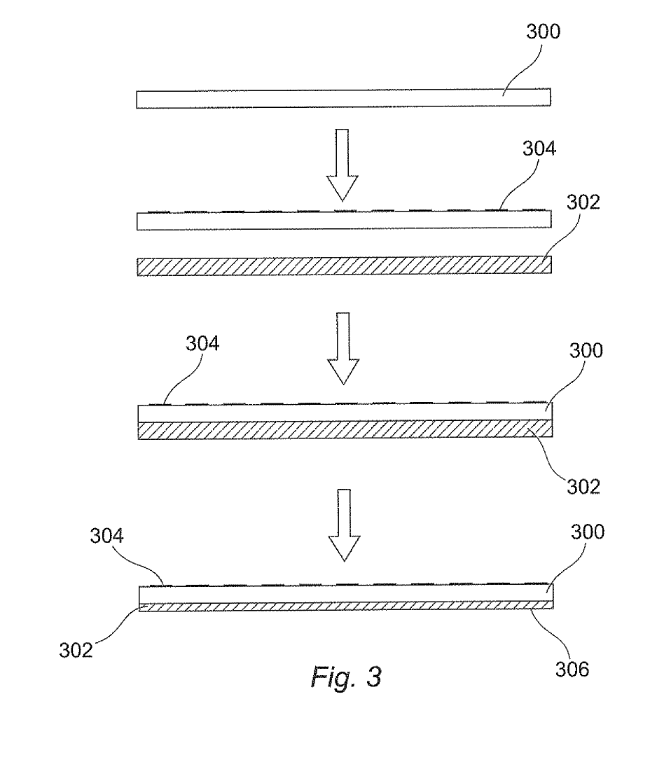

Referring to FIG. 3, a glass wafer 300 and silicon wafer 302 are shown. A filter layer 304 is applied to the glass wafer by a vapor deposition coating process using shadow masking. Shadow masking means that the coating that forms the filter is not continuous, and an element of the coating is applied to align with each individual CSP. This compression stresses caused by the coating may be localized to the local die area for the filter in question. As a result, there is less compression stress on the glass wafer and a low warp configuration is retained.

The glass wafer may then be bonded with the silicon wafer, and any subsequent backgrind process may result in significantly less thickness variations that would be detrimental to the TSV process. The final silicon glass combination or laminate is shown as 306.

The shadow mask (not shown) may be a contact mask or near contact mask having a reduced height to allow the first filter characteristics to remain within the requirements for a clear aperture at the upper surface of the CSP for the final resulting camera. The mask is in the form of a grid that coincides with the “step repeat” of the sensors on the silicon wafer. This may ensure that each filter is correctly positioned relative to the final individual CSPs.

As described, the filter is applied before bonding the silicon and glass layers. However, the filter could be applied after the two layers have been bonded together.

The filter is formed of an appropriate material depending on the frequency for transmission and suppression of radiation. For a UV-IR filter, a typical material may include multiple thin film layers of silicon oxide with silicon nitride. Similarly different materials for the glass wafer and silicon wafer may be appropriate in different circumstances. For example, borosilicate or alumino-silicate float drawn glasses.

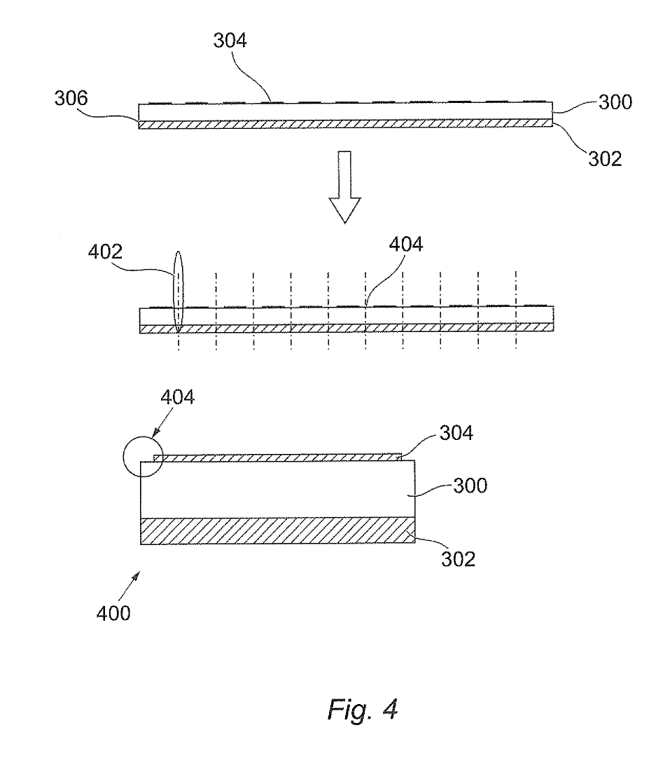

FIG. 4 shows the next stages of the process where the combined silicon glass laminate with filters may be cut into individual CSP modules 400. The cuts are made with a wafer saw 402 in alignment with the gaps between the filter coating, which have been applied by the mask. Due to the size of the gaps between the filter coating, the filter material may never come in contact with the saw blade, and thus may avoid chipping or delamination of the filter coating as seen at 404.

As a consequence of the grid-like filter layer, there are less stresses between the filter coating and the glass wafer. Thus bowing and warping of the overall package which could ultimately result in stress failure of the module may be reduced or avoided. As a first approximation, the linear stress in the module may be reduced by a ratio of the dimension of the coated area to that of the step repeat distance in that direction.

A significant advantage is that, as stress is reduced, the ability to tune the filter to give optical and reliability properties may come before the reduction of stress. This provides more flexibility in the design process, and may enable an improved optical standard to be achieved.

An advantage over implementing the filter in a two sided coating is that near field defect criteria, where defects are compared to pixel size, are reduced and may be substantially removed. Instead, with the present embodiments, the size of the allowable defects is based upon the exit pupil of the objective lens, and not the effects of the coating.

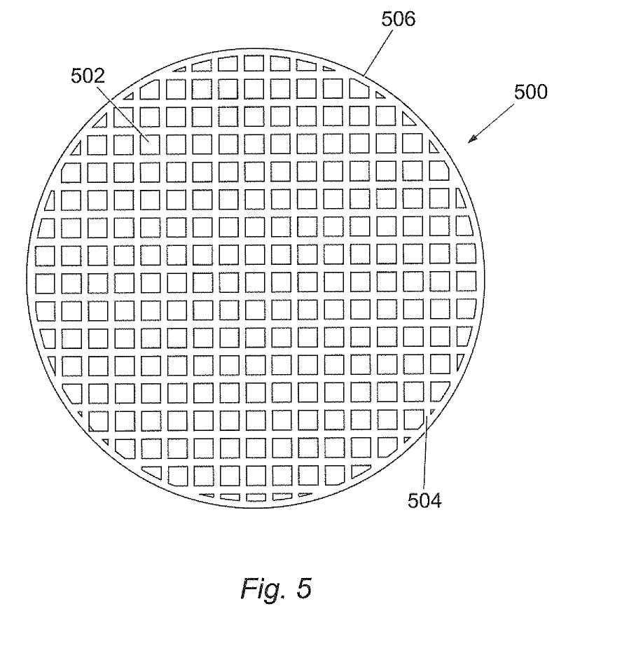

FIG. 5 shows the top view of a glass/silicon laminate including a layer of filter coating in the form of the grid 500. The coated areas 502 coincide with the optical clear aperture in the filter layer, and the uncoated areas coincide with the “sawing streets” 504, which enable the wafer to be cut into individual CSP modules. There is also an uncoated border 506.

It will be appreciated that the grid may take many different forms depending on the underlying arrangement of sensors or other devices which require this type of filter. The grid may be regular or irregular and the relative sizes of this filter and the gap between may also be variable. It should be noted that reference to light or radiation is intended to encompass all frequencies of radiation in which a digital image sensor may operate.

The application of a filter in accordance with the present embodiments may be applied to any combination of material, not just glass and silicon as described herein. The application of the filter may apply to any situation where warping due to thermal expansion differences occurs.

The digital image sensor in accordance with the present embodiments is suitable for use in any device which makes use of a digital image sensor. For example, the digital image sensor may be used in a camera, in camera modules, or in a mobile telephone or any other computer related equipment. It will be appreciated that the embodiments may be varied in many different ways and still remain within the intended scope of and spirit of the invention.

1-13. (canceled)

14. A method of forming image sensor devices comprising:
applying a filter layer to a cover layer by
masking the cover layer with a pattern, and
applying the filter layer using a deposition process; and
bonding the cover layer to a sensor layer including a plurality of image sensors;
the pattern defining an alignment between the filter layer and each of the plurality of image sensors, and defining gaps in the filter layer around each of the plurality of image sensors.

15. The method of claim 14, further comprising bonding the cover layer to the sensor layer after applying the filter layer.

16. The method of claim 14, further comprising cutting the cover layer, and the sensor layer to define the image sensor devices.

17. The method of claim 14, wherein applying the filter layer comprises applying a shadow mask adjacent the cover layer.

18. The method of claim 14, wherein applying the filter layer comprises applying the filter layer using a vapor deposition process.

19. The method of claim 14, wherein the sensor layer comprises a silicon sensor layer.

20. The method of claim 14, wherein the cover layer comprises a glass cover layer.

21. The method of claim 14, wherein the filter layer comprises an ultraviolet-infrared (UV-IR) filter layer.

22. A method of forming an integrated circuit image sensor device comprising:
forming a sensor layer;
forming a cover layer to be carried by the sensor layer; and
forming a filter layer on the cover layer and having peripheral edges spaced inwardly from adjacent peripheral edges of the sensor layer and the cover layer.

23. The method of claim 22, further comprising bonding the cover layer to the sensor layer after forming the filter layer.

24. The method of claim 22, wherein forming the filter layer comprises applying a shadow mask adjacent the cover layer.

25. The method of claim 22, wherein forming the filter layer comprises applying the filter layer using a vapor deposition process.

26. The method of claim 22, wherein the sensor layer comprises a silicon sensor layer.

27. The method of claim 22, wherein the cover layer comprises a glass cover layer.

28. The method of claim 22, wherein the filter layer comprises an ultraviolet-infrared (UV-IR) filter layer.

29. A semiconductor wafer comprising:
a sensor layer comprising a plurality of image sensors;
a cover layer carried by said sensor layer; and
a filter layer on said cover layer;
said filter layer having a plurality of gaps defined therein, the plurality of gaps being aligned with and around each of the plurality of image sensors.

30. The semiconductor wafer of claim 29, wherein said sensor layer comprises a silicon sensor layer.

31. The semiconductor wafer of claim 29, wherein said cover layer comprises a glass cover layer.

32. The semiconductor wafer of claim 29, wherein said filter layer comprises an ultraviolet-infrared (UV-IR) filter layer.

33. An integrated circuit image sensor device comprising:
a sensor layer;
a cover layer carried by said sensor layer; and
a filter layer on said cover layer and having peripheral edges spaced inwardly from adjacent peripheral edges of said sensor layer and said cover layer.

34. The integrated circuit image sensor device of claim 33, wherein said sensor layer comprises a silicon sensor layer.

35. The integrated circuit image sensor device of claim 33, wherein said cover layer comprises a glass cover layer.

36. The integrated circuit image sensor device of claim 33, wherein said filter layer comprises an ultraviolet-infrared (UV-IR) filter layer.
